(19) United States
(12) Patent Application Publication
(10) Pub. No.: US 2022/0173021 A1
(43) Pub. Date: Jun. 2, 2022

(54) SEMICONDUCTOR DEVICE, CORRESPONDING MANUFACTURING METHODS AND COMPONENT

(71) Applicant: STMicroelectronics S.r.l., Agrate Brianza (MB) (IT)

(72) Inventor: Antonio CANNAVACCIUOLO, Milan (IT)

(73) Assignee: STMicroelectronics S.r.l., Agrate Brianza (MB) (IT)

(21) Appl. No.: 17/539,653

(22) Filed: Dec. 1, 2021

(30) Foreign Application Priority Data
Dec. 2, 2020 (IT) 102020000029441

(51) Int. Cl. H01L 23/495; H01L 23/31; H01L 21/56; H01L 21/48

(52) U.S. Cl. CPC H01L 23/49541; H01L 21/4828; H01L 21/56; H01L 23/3107

(57) ABSTRACT

A semiconductor device includes a leadframe having a semiconductor chip arranged thereon and an electrically-insulating encapsulation molded onto the leadframe and the semiconductor chip. The leadframe is a pre-molded leadframe including a coupling surface having an alternation of electrically-conductive parts and insulating parts between electrically-conductive parts. The coupling surface includes a pattern of grooves and the electrically-insulating encapsulation includes anchoring protrusions extending into the grooves of the pattern of grooves in the coupling surface.

### PRIORITY CLAIM

This application claims the priority benefit of Italian Application for Patent No. 102020000029441, filed on Dec. 2, 2020, the content of which is hereby incorporated by reference in its entirety to the maximum extent allowable by law.

### TECHNICAL FIELD

The description relates to semiconductor devices.

One or more embodiments may be applied to semiconductor devices such as integrated circuits (ICs), for instance.

### BACKGROUND

Quad Flat No-leads (QFN) packages having peripheral lands at the package bottom in order to provide electrical connection to a substrate such as a printed circuit board (PCB) are exemplary of semiconductor devices which may benefit from using pre-molded leadframes.

A QFN package may also include an exposed thermally-conductive pad to improve heat dissipation.

A pre-molded leadframe includes resin/plastic material around the metal leads and the die paddles onto which semiconductors chips or dice are attached; a molding compound (epoxy resin, for instance) is subsequently molded onto the chips or dice attached onto the pre-molded leadframe.

Undesired molding compound/lead delamination may be observed in semiconductor devices such as QFN packages including pre-molded leadframes during reliability tests such as moisture sensitivity level (MSL) and thermal cycles. Such delamination can produce wire break and electrical failure of the package.

Various attempts at countering delamination have included improvements in molding compound formulation or increasing leadframe roughness with the aim of improving molding compound/leadframe adhesion.

Such approaches suffer from various drawbacks.

For instance, changes in molding compound formulation may translate into a higher cost, workability/moldability issues and the need for new qualification/evaluation (DoEs).

Increasing leadframe roughness to improve molding compound/leadframe adhesion may likewise result in higher costs in comparison with standard leadframe finishing. Additionally, increasing leadframe roughness can adversely affect a wire bonding process.

There is a need in the art to contribute in providing improved solutions addressing drawbacks of prior art solutions as discussed in the foregoing.

### SUMMARY

One or more embodiments may relate to a semiconductor device.

One or more embodiments may relate to a corresponding component. A pre-molded leadframe may be exemplary of such a component.

One or more embodiments may relate to corresponding methods.

One or more embodiments may provide chemical-mechanical locking of a molding compound on the leads resulting from leadframe design.

One or more embodiments effectively counter molding compound/lead delamination and facilitate avoiding mechanical stress on wire bonding stitches during thermal-cycles.

One or more embodiments provide improved adhesion while avoiding increased leadframe roughness, changes in molding compound formulation and/or adverse effects on wire bonding processes.

One or more embodiments are compatible with a variety of final leadframe finishing (copper, pre-plated leadframe (PPF), and so on) and a variety of packages such as Quad Flat No-leads (QFN) packages, for instance.

One or more embodiments lend themselves to being implemented with various technologies such as, for instance: selective pre-mold removal via laser beam energy, selective copper removal with an etching process, or selective copper growth on leads with a copper plating process.

### BRIEF DESCRIPTION OF THE DRAWINGS

One or more embodiments will now be described, by way of example only, with reference to the annexed figures, wherein:

FIG. 1 is a plan (top) view of a semiconductor device to which embodiments as discussed herein may be apply,

FIG. 2 is a cross-sectional view along line II-II in FIG. 1, reproduced on an enlarged scale and illustrative of a conventional solution in a semiconductor device as illustrated in FIG. 1,

FIG. 3 is a cross-sectional view corresponding to the cross-sectional view of FIG. 2, again reproduced on an enlarged scale and illustrative of the application of embodiments as per the present description in a semiconductor device as illustrated in FIG. 1,

FIGS. 4A to 4C illustrate a first example of steps in a method of manufacturing which implements an embodiment as per the present description,

FIGS. 5A to 5C illustrate a second example of steps in a method of manufacturing which implements an embodiment as per the present description, and

FIGS. 6A to 6C illustrate a third example of steps in a method of manufacturing which implements an embodiment as per the present description.

It will be appreciated that, for the sake of clarity and ease of understanding, the various figures may not be drawn to a same scale.

### DETAILED DESCRIPTION

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular conformations, structures, or characteristics may be combined in any adequate way in one or more embodiments.

The headings/references used herein are provided merely for convenience and hence do not define the extent of protection or the scope of the embodiments.

Also, throughout the figures, unless the context indicates otherwise, like parts or elements are indicated with like reference symbols, and a corresponding description will not be repeated for each and every figure for brevity.

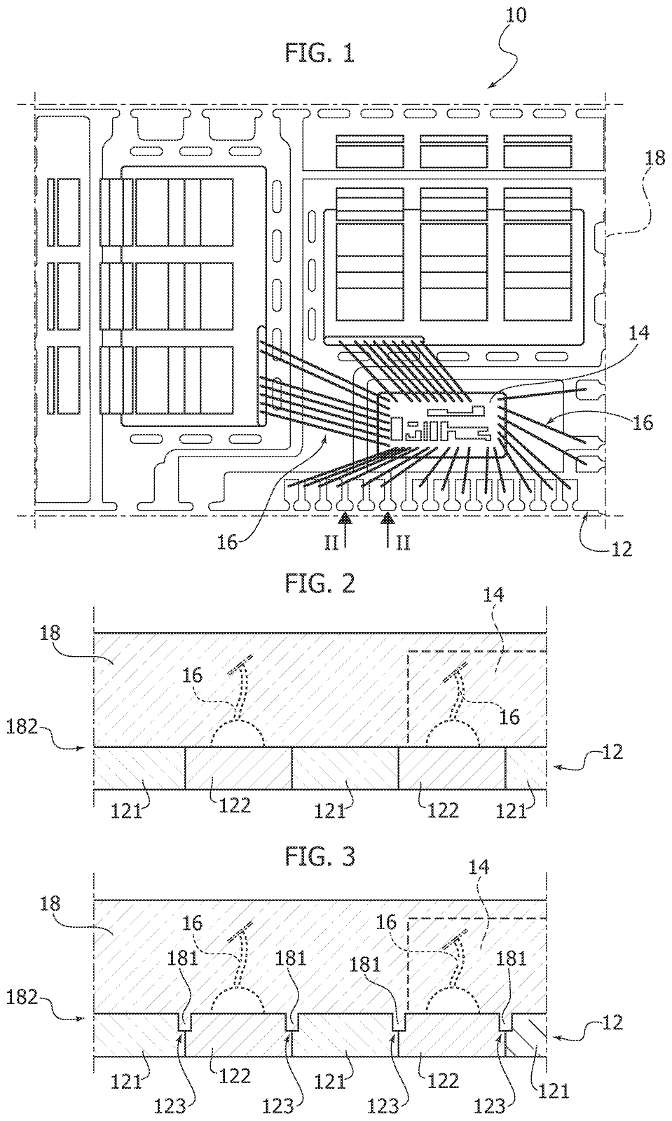

FIG. 1 is a plan (top or front) view of a semiconductor device 10 of the Quad Flat No-leads (QFN) type. Such device packages have peripheral lands at the package bottom in order to provide electrical connection to a substrate such as a printed circuit board or PCB (not visible in the figures).

Those of skill in the art will otherwise appreciate that this type of device is just exemplary of a variety of semiconductor devices where delamination as discussed previously may occur. Consequently, while a Quad Flat No-leads (QFN) semiconductor device is considered herein as an example, the embodiments are not limited to the possible use in QFN semiconductor devices.

As conventional in the art, a device 10 as exemplified herein may comprise a substrate such as a so-called leadframe (or lead frame) 12 including at least one die pad or paddle onto which a semiconductor chip or die 14 can be mounted (attached) and an array of electrically-conductive leads around the die pad.

The leads in the leadframe 12 are intended to provide electrical contact according to a desired electrically-conductive routing pattern for the semiconductor chip or die 14.

The designation leadframe (or lead frame) is currently used (see, for instance the USPC Consolidated Glossary of the United States Patent and Trademark Office) to indicate a metal frame which provides support for a semiconductor chip or die as well as electrical leads to couple the semiconductor chip or die to other electrical components or contacts.

Essentially, a leadframe comprises an array of electrically-conductive formations (leads) which from a peripheral location extend inwardly in the direction of the semiconductor chip or die 14, thus forming an array of electrically-conductive formations from the die pad having at least one semiconductor chip or die attached thereon. This may be via a die attach adhesive (a die attach film (DAF), for instance).

Electrical coupling of the leads in the leadframe 12 with the semiconductor chip or die 14 may be via wires forming a wire-bonding pattern 16 around the chip or die 14.

An electrically-insulating encapsulation of the device 10 can be provided by a molding compound 18 molded onto the leadframe 12 and the semiconductor chip or die 14, as well as on the wire bonding pattern 16 and other components mounted of the leadframe 12. While not expressly referenced for simplicity, examples of these are visible in FIG. 1.

An arrangement as discussed in the foregoing is conventional in the art, which makes it unnecessary to provide a more detailed description herein.

Also, certain embodiments may contemplate replacing conventional wire bonding such as 16 with electrically conductive formations such as traces and vias formed by laser activation of a molding compound 18 suited for laser direct structuring (LDS) processing.

It is otherwise noted that the details of wire bonding 16 (or alternative solutions as mentioned above) are not of particular relevance for the embodiments.

The cross-sectional view of FIG. 2 is exemplary of the (per se likewise conventional) possibility for a device such as 10 to include a pre-molded leadframe 12, that is a leadframe including resin/plastic material 121 around the metal leads 122 (and the die paddles) onto which a semiconductor chip or die 14 is attached. A wire bonding pattern 16 may be provided for coupling metal leads 122 in the leadframe 12 with the semiconductor chip or die 14 (at bonding pads provide at the top or front surface of the chip or die, for instance).

In FIG. 2 (and FIG. 3 as well) a semiconductor chip or die 14 attached on the leadframe 12 and a pair of bonding wires 16 is schematically represented in dashed outline.

As exemplified in FIG. 2, at the surface 182 onto which the compound 18 is molded, the leadframe 12 exhibits an alternation of resin/plastic (“pre-mold”) material (at 121) and metal leads (at 122).

As discussed in the introductory portion of the description, undesired molding compound/lead delamination may be observed at the surface 182, which can produce wire break (at bonding wire 16) and electrical failure of the package. Also, attempts at countering delamination via improvements in molding compound formulation or increased leadframe roughness were found to suffer from certain drawbacks.

FIG. 3 is generally illustrative, by way of direct comparison with FIG. 2, of the possibility of countering undesired delamination at the surface 182 by bestowing onto that surface a sculptured design including grooves (channels) 123 into which the molding compound 18 can penetrate during the molding process to form protrusions 181 which extend into the grooves 123. In that way, the encapsulation provided by the molding compound 18 can become firmly anchored, thus effectively countering delamination with respect to the leads in the leadframe, as a result of the molding compound undergoing solidification (that is, the process when a flowing, molten mass becomes a solid, due to cooling/curing) and forming the anchoring protrusions 181.

The sculptured appearance of the surface 182 as provided via the (for instance, elongate) grooves or channels 123 can be formed by resorting to various options of machining/processing and a manufacturing process.

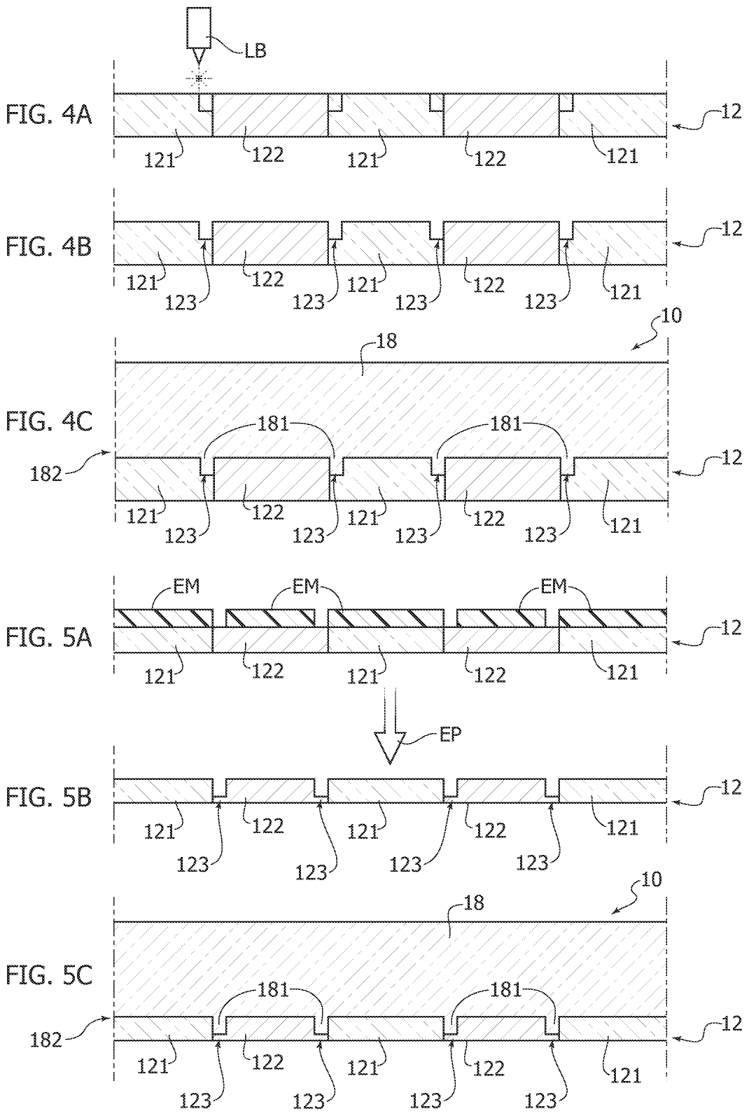

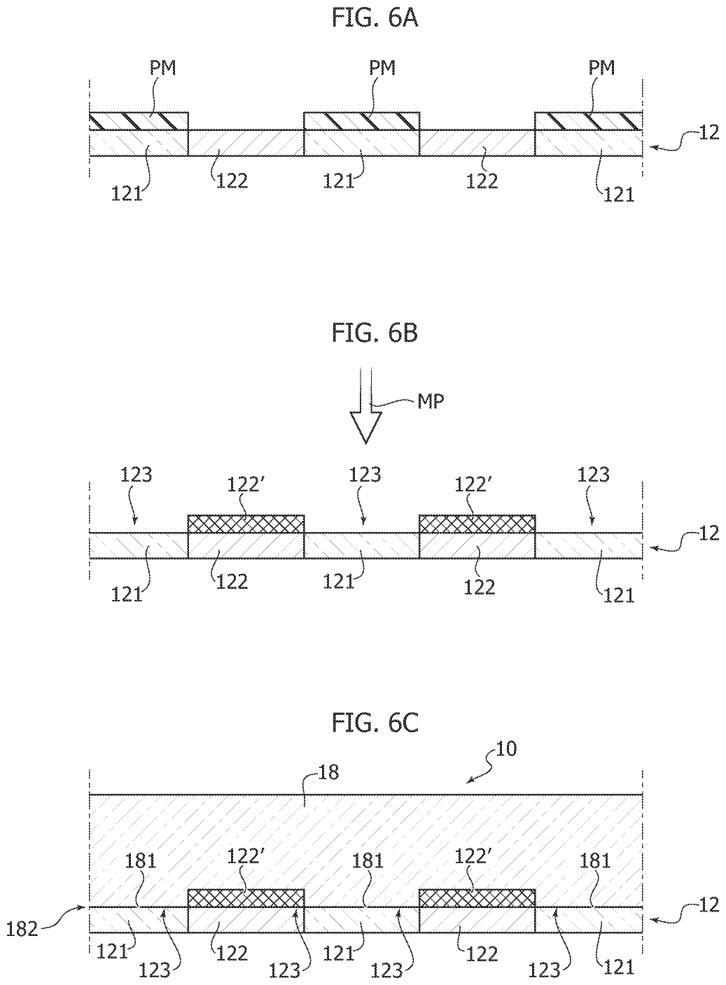

As discussed in the following, these options may include, by way of non-limiting examples: selective removal of pre-mold material at 121 through laser beam energy (FIGS. 4A to 4C); selective removal of metal (for instance copper) material at 122 with a (for instance chemical) etching process (FIGS. 5A to 5C); or selective growth of metal (for instance copper) with a plating process (FIGS. 6A to 6C).

Whatever the option adopted, one or more embodiments may advantageously result in grooves or channels 123 (and corresponding protrusions 181) which are co-extensive with the lead pattern of the leadframe 12.

That is, one or more embodiments may advantageously produce grooves or channels 123 (and protrusions 181) which, irrespective of the grooves or channels 123 being formed in the pre-mold material (FIGS. 4A to 4C) or in the lead material (FIGS. 5A to 5C), extend at a borderline between resin/plastic pre-mold material at 121 and a lead 122. The same also applies to the embodiments of FIGS. 6A to 6C, where the grooves or channels 123 are defined at their bottom side by pre-mold material at 121 and at their lateral sides by lead material at 122.

Such “co-extensiveness” of the grooves or channels 123 (and the protrusions 181) with the lead pattern of the leadframe 12 was found to be advantageous in providing strong anchoring of the molding compound 18 to the leadframe 12.

FIGS. 4A to 4C are exemplary of embodiments where a (metal, for instance copper) leadframe is provided including die-pads and leads (as exemplified at 122) and pre-mold material (resin/plastic material, for instance) is molded (as exemplified at 121) around the metal parts of the leadframe to obtain—in a conventional manner—a pre-molded leadframe 12 including an alternation of metal parts and parts of pre-mold material as illustrated at 121, 122 in FIG. 4A.

Laser beam energy is then selectively applied as represented by LB. This may occur in a manner known per se to those of skill in the art, for instance via a computer-controlled laser source whose beam can be steered over the surface 182).

In that way the pre-mold material can be removed at locations (of the pre-mold material 121) neighboring the metal parts 122 so that grooves or channels 123 are formed (in the pre-mold material 121) as exemplified in FIG. 4B.

It is noted that no etching mask is involved in such a step insofar as the laser beam LB can be selectively steered (under computer control, as per se conventional in the art) to locally remove the pre-mold resin to form the grooves or channels 123.

Such processing can take place independently of (for instance either before or after) attaching the die or dice 14 onto the leadframe 12 and possibly providing wire bonding 16: neither of these is visible in the figures for simplicity.

A molding compound as illustrated at 18 can then be molded onto the resulting assembly (pre-molded leadframe 12, die or dice 14 and, possibly, wire bonding 16). The material 18 molded will thus penetrate into the grooves or channels 123 as exemplified in FIG. 4C and become firmly anchored therein, thus countering delamination as discussed previously via the protrusions 181 extending into the grooves 123.

FIGS. 5A to 5C are exemplary of embodiments where a (metal, for instance, copper) leadframe is again provided including die-pads and leads (as exemplified at 122) and pre-mold material (resin/plastic material, for instance) is molded (as exemplified at 121) around the metal parts of the leadframe to obtain—in a conventional manner—a pre-molded leadframe 12 including an alternation of metal parts and parts of pre-mold material at 121, 122.

As illustrated in FIG. 5A, an etching mask EM can be applied that is shaped and dimensioned (again in a manner known per se to those of skill in the art) in order to facilitate (for instance chemical) etching—see, for instance, EP in FIG. 5B—of the metal material 122 at locations (of the metal material 122) neighboring the pre-mold material parts 121 so that grooves or channels 123 are formed (in the metal material 122) as exemplified in FIG. 5B.

Advantageously, such processing can take place before attaching the die or dice 14 onto the leadframe 12 and, possibly, providing wire bonding 16.

Again, a molding compound as illustrated at 18 can then be molded onto the resulting assembly (pre-molded leadframe 12, die or dice 14 and, possibly, wire bonding 16). The material 18 molded will thus penetrate into the grooves or channels 123 as exemplified in FIG. 5C and become firmly anchored therein thus countering delamination as discussed previously via the protrusions 181 extending into the grooves 123.

FIGS. 6A to 6C are exemplary of embodiments where a (metal, for instance copper) leadframe is once more provided including die-pads and leads (as exemplified at 122) and pre-mold material (resin/plastic material, for instance) is molded (as exemplified at 121) around the metal parts of the leadframe to obtain—in a conventional manner—a pre-molded leadframe 12 including an alternation of metal parts and parts of pre-mold material as illustrated at 121, 122 in FIG. 6A.

As illustrated in FIG. 6A, a plating mask PM can be applied shaped and dimensioned (again in a manner known per se to those of skill in the art) in order to cover the pre-mold material parts 121 while leaving the metal parts 122 exposed, that is, uncovered.

A metal plating process (for instance electro-plating) can be applied as exemplified at MP in FIG. 6 in order to facilitate metal (for instance, copper) growth 122′ at the locations left uncovered by the mask PM, that is at the metal parts 122. It is noted that the mask PM is beneficial in avoiding undesired “mushroom” effects at the metal parts 122 and over-plating of the entire leadframe.

As a result of metal growth (as illustrated at 122′ in FIG. 6B) the height or depth of the metal parts 122 will be increases, this once more resulting in the formation of grooves or channels 123 in the surface 182, with these grooves or channels are defined at their bottom side by pre-mold material at 121 and at their lateral sides by metal material at 122.

Advantageously, such processing can take place before attaching the die or dice 14 onto the leadframe 12 and, possibly, providing wire bonding 16.

A molding compound as illustrated at 18 can then be molded onto the resulting assembly (pre-molded leadframe 12, die or dice 14 and, possibly, wire bonding 16). The material 18 molded will thus penetrate into the grooves or channels 123 as exemplified in FIG. 6C and become firmly anchored therein thus countering delamination as discussed previously via the protrusions 181 extending into the grooves 123.

Whatever the specific implementing options adopted, one or more embodiments facilitate countering delamination with improved reliability of locking of the molding compound (with a possible increase of metal height—see 122′ in FIGS. 6B and 6C and/or in co-operation with chemical adhesion between pre-mold and molding compounds), while achieving considerable savings in terms of cost and time (in terms of process DoEs, new material qualification, and so on).

It is noted that one or more embodiments may take the form of a pre-molded leadframe 12 “grooved” or “channeled” at 123 suited to be provided as an intermediate product by a leadframe supplier in view of completion by die mounting, wire bonding and package molding during semiconductor device manufacturing.

A device (for instance, 10) as exemplified herein may comprise: a leadframe (for instance, 12) having at least one semiconductor chip (for instance, 14) arranged thereon; and an electrically-insulating encapsulation (for instance, 18) molded onto the leadframe and the at least one semiconductor chip arranged thereon.

In a device as exemplified herein: the leadframe may include a coupling surface (for instance, 182) of the leadframe to the electrically-insulating encapsulation, the coupling surface comprising an alternation of electrically-conductive parts (for instance, 122) and electrically-insulating parts (for instance, 121) between electrically-conductive parts (for instance, electrically-conductive parts such as 122 having insulating parts molded therebetween); wherein said coupling surface may have a pattern of grooves (for instance, 123) formed therein, wherein the electrically-insulating encapsulation may include anchoring protrusions (for instance, 181) extending into the grooves of said pattern of grooves in said coupling surface.

In a device as exemplified herein, the grooves of said pattern of grooves may extend at borderline locations between electrically-conductive parts and insulating parts therebetween at said coupling surface (see, for instance, FIGS. 3, 4B, 5B and 6B).

In a device as exemplified herein, the grooves of said pattern of grooves may be formed in at least one insulating part at said coupling surface (see, for instance, FIG. 4B).

In a device as exemplified herein, the grooves of said pattern of grooves may be formed in at least one electrically-conductive part at said coupling surface (see, for instance, FIG. 5B).

In a device as exemplified herein, the alternation of electrically-conductive parts and insulating parts between electrically-conductive parts at said coupling surface comprises thicker (for instance, 122, 122′) and thinner (for instance, 121) parts, wherein the grooves of said pattern of grooves have a bottom wall at one of said thinner parts and two side walls provided by two said thicker parts neighboring said one of said thinner parts (see, for instance, FIG. 6B with a bottom wall at 121 two side walls provided by two neighboring thicker parts at 122, 122′).

A method as exemplified herein may comprise: molding an electrically-insulating encapsulation (for instance, 18) onto a leadframe (for instance, 12) having at least one semiconductor chip (for instance, 14) arranged thereon, wherein the electrically-insulating encapsulation is coupled to the leadframe at a coupling surface comprising an alternation of electrically-conductive parts and electrically-insulating parts between electrically-conductive parts; and forming in said coupling surface a pattern of grooves (for instance, 123), wherein the electrically-insulating encapsulation molded thereon extends into the grooves of said pattern of grooves in said coupling surface providing anchoring protrusions (for instance, 181) of the electrically-insulating encapsulation to the leadframe.

A method as exemplified herein may comprise forming the grooves of said pattern of grooves in said coupling surface at borderline locations between electrically-conductive parts and insulating parts therebetween at said coupling surface (see, for instance, FIGS. 3, 4B, 5B and 6B).

A method as exemplified herein may comprise forming the grooves of said pattern of grooves in said coupling surface in at least one insulating part at said coupling surface by selectively removing, optionally via laser processing (for instance, LB), insulating material therefrom.

A method as exemplified herein may comprise forming the grooves of said pattern of grooves in said coupling surface in at least one electrically-conductive part of said coupling surface by selectively removing, optionally via etching (for instance, EP), electrically-conductive material therefrom.

A method as exemplified herein may comprise forming, optionally via metal growth (for instance, 122′) at electrically-conductive parts, thicker (for instance, 122, 122′) and thinner (for instance, 121) parts in the alternation of electrically-conductive parts and insulating parts between electrically-conductive parts at said coupling surface, wherein the grooves (123) of said pattern of grooves have a bottom wall at one of said thinner parts and two side walls provided by two said thicker parts neighboring said one of said thinner parts (see, for instance, FIG. 6B with a bottom wall at 121 two side walls provided by two neighboring thicker parts at 122, 122′).

A leadframe for use (possibly as a stand-alone intermediate product supplied by a supplier to a semiconductor device manufacturer) in a device as exemplified herein may include: said coupling surface (for instance, 182) of the leadframe (for instance, 12) to the electrically-insulating encapsulation, the coupling surface comprising said alternation of electrically-conductive parts (for instance, 122) and (electrically-) insulating parts between electrically-conductive parts; wherein said coupling surface hasg said pattern of grooves (123) formed therein.

Advantageously, in such a leadframe, the grooves of said pattern of grooves may extend at borderline locations between electrically-conductive parts and insulating parts therebetween at said coupling surface.

Advantageously, a method of manufacturing such a leadframe may comprise forming the grooves of said pattern of grooves in said coupling surface by one of: forming the grooves of said pattern of grooves in said coupling surface in at least one insulating part at said coupling surface selectively removing, preferably via laser processing, insulating material therefrom; or forming the grooves of said pattern of grooves in said coupling surface in at least one electrically-conductive part at said coupling surface selectively removing, preferably via etching, electrically-conductive material therefrom; or forming, preferably by metal growth at electrically-conductive parts, thicker and thinner parts in the alternation of electrically-conductive parts and insulating parts between electrically-conductive parts at said coupling surface, wherein the grooves of said pattern of grooves have a bottom wall at one of said thinner parts and two side walls provided by two said thicker parts neighboring said one of said thinner parts.

Without prejudice to the underlying principles, the details and the embodiments may vary, even significantly, with respect to what has been described by way of example only without departing from the scope of the embodiments.

The claims are an integral part of the technical disclosure provided herein in connection with the embodiments.

The extent of protection is determined by the annexed claims.

1. A device, comprising:
a leadframe;
at least one semiconductor chip arranged on the leadframe;
an electrically-insulating encapsulation molded onto the leadframe and the at least one semiconductor chip;
wherein the leadframe includes a coupling surface relative to the electrically-insulating encapsulation, wherein the coupling surface is defined by an alternation of electrically-conductive parts and insulating parts between electrically-conductive parts;
wherein said coupling surface includes a pattern of grooves; and
wherein the electrically-insulating encapsulation includes anchoring protrusions extending into grooves of said pattern of grooves of said coupling surface.

2. The device of claim 1, wherein the grooves of said pattern of grooves extend at borderline locations where electrically-conductive parts are adjacent insulating parts at said coupling surface.

3. The device of claim 2, wherein the grooves of said pattern of grooves are formed in the insulating parts at said coupling surface.

4. The device of claim 2, wherein the grooves of said pattern of grooves are formed in the electrically-conductive parts at said coupling surface.

5. The device of claim 1, wherein the alternation of electrically-conductive parts and insulating parts forms said coupling surface defined by first thickness parts and second thickness parts thinner than the first thickness parts, and wherein the grooves of said pattern of grooves have a bottom wall at said second thickness parts and two side walls provided by two first thickness parts neighboring each said second thickness part.

6. The device of claim 5, wherein the first thickness parts are electrically-conductive parts and the second thickness parts are insulating parts.

7. The device of claim 6, wherein the first thickness parts are formed by a metal growth layer present at an upper surface of the electrically-conductive parts.

8. A method, comprising:
molding an electrically-insulating encapsulation onto a leadframe having at least one semiconductor chip arranged thereon, wherein the electrically-insulating encapsulation is coupled to the leadframe at a coupling surface comprising an alternation of electrically-conductive parts and insulating parts between electrically-conductive parts; and
forming a pattern of grooves in said coupling surface;
wherein molding comprises having the electrically-insulating encapsulation extend into the grooves of said pattern of grooves in said coupling surface providing anchoring protrusions of the electrically-insulating encapsulation to the leadframe.

9. The method of claim 8, comprising forming grooves of said pattern of grooves in said coupling surface at borderline locations between electrically-conductive parts and insulating parts therebetween at said coupling surface.

10. The method of claim 8, comprising forming grooves of said pattern of grooves in said coupling surface in at least one insulating part at said coupling surface by selectively removing insulating material therefrom.

11. The method of claim 10, wherein selectively removing comprises performing a laser processing of the insulating material of the at least one insulating part.

12. The method of claim 8, comprising forming grooves of said pattern of grooves in said coupling surface in at least one electrically-conductive part at said coupling surface by selectively removing electrically-conductive material therefrom.

13. The method of claim 12, wherein selectively removing comprises etching the electrically-conductive material of the at least one electrically-conductive part.

14. The method of claim 8, comprising forming first thickness parts and second thickness parts in the alternation of electrically-conductive parts and insulating parts at said coupling surface, wherein the grooves of said pattern of grooves have a bottom wall at one of said second thickness parts and two side walls provided by two said first thickness parts neighboring said one of said second thickness parts.

15. The method of claim 14, wherein forming comprises performing a metal growth at electrically-conductive parts to provide said first thickness parts.

16. A leadframe, comprising:
an alternation of electrically-conductive parts and insulating parts between electrically-conductive parts;
wherein said alternation defines a coupling surface of the leadframe having a pattern of grooves formed therein.

17. The leadframe of claim 16, wherein the grooves of said pattern of grooves extend at borderline locations where electrically-conductive parts are adjacent insulating parts at said coupling surface.

18. The leadframe of claim 17, wherein the grooves of said pattern of grooves are formed in the insulating parts at said coupling surface.

19. The leadframe of claim 17, wherein the grooves of said pattern of grooves are formed in the electrically-conductive parts at said coupling surface.

20. The leadframe of claim 16, wherein the alternation of electrically-conductive parts and insulating parts forms said coupling surface defined by first thickness parts and second thickness parts thinner than the first thickness parts, and wherein the grooves of said pattern of grooves have a bottom wall at said second thickness parts and two side walls provided by two first thickness parts neighboring each said second thickness part.

21. The leadframe of claim 20, wherein the first thickness parts are electrically-conductive parts and the second thickness parts are insulating parts.

22. The leadframe of claim 21, wherein the first thickness parts are formed by a metal growth layer present at an upper surface of the electrically-conductive parts.

23. A method of manufacturing a leadframe, comprising:
forming an alternation of electrically-conductive parts and insulating parts between electrically-conductive parts; and
forming a pattern of grooves in a coupling surface defined by said alternation.

24. The method of claim 23, comprising forming grooves of said pattern of grooves in said coupling surface at borderline locations between electrically-conductive parts and insulating parts therebetween at said coupling surface.

25. The method of claim 23, comprising forming grooves of said pattern of grooves in said coupling surface in at least one insulating part at said coupling surface by selectively removing insulating material therefrom.

26. The method of claim 25, wherein selectively removing comprises performing a laser processing of the insulating material of the at least one insulating part.

27. The method of claim 23, comprising forming grooves of said pattern of grooves in said coupling surface in at least one electrically-conductive part at said coupling surface by selectively removing electrically-conductive material therefrom.

28. The method of claim 27, wherein selectively removing comprises etching the electrically-conductive material of the at least one electrically-conductive part.

29. The method of claim 23, comprising forming first thickness parts and second thickness parts in the alternation of electrically-conductive parts and insulating parts at said coupling surface, wherein the grooves of said pattern of grooves have a bottom wall at one of said second thickness parts and two side walls provided by two said first thickness parts neighboring said one of said second thickness parts.

30. The method of claim 29, wherein forming comprises performing a metal growth at electrically-conductive parts to provide said first thickness parts.
